(19) United States
(12) Patent Application Publication
(10) Pub. No.: US 2025/0104969 A1
(43) Pub. Date: Mar. 27, 2025

(54) SUBSTRATE PROCESSING APPARATUS AND A SUBSTRATE PROCESSING METHOD USING THE SAME

(71) Applicant: SAMSUNG ELECTRONICS CO., LTD., SUWON-SI (KR)

(72) Inventors: HYUN BAE KIM, Suwon-si (KR); JUHO LEE, Suwon-si (KR); HYEONGMO KANG, Suwon-si (KR); KYUNG-SUN KIM, Suwon-si (KR); NAM KYUN KIM, Suwon-si (KR); DONGHYEON NA, Suwon-si (KR); SANG KI NAM, Suwon-si (KR); HYUNJAE LEE, Suwon-si (KR); HYUNHAK JEONG, Suwon-si (KR)

(21) Appl. No.: 18/640,332

(22) Filed: Apr. 19, 2024

(30) Foreign Application Priority Data
Sep. 26, 2023 (KR) 10-2023-0129081

(51) Int. Cl. H01J 37/32

(52) U.S. Cl. CPC H01J 37/32146; H01J 37/32715; H01J 2237/2007

(57) ABSTRACT

A substrate processing method including: placing a substrate in a substrate processing apparatus; applying source power to the substrate processing apparatus; and applying bias power to the substrate processing apparatus, wherein applying the source power to the substrate processing apparatus includes: providing the substrate processing apparatus with a first radio-frequency (RF) power with a first pulse having a first period; and providing the substrate processing apparatus with a second RF power with a second pulse having a second period, wherein the first period is longer than the second period.

### CROSS-REFERENCE TO RELATED APPLICATION

This U.S. nonprovisional application claims priority under 35 U.S.C. § 119 to Korean Patent Application No. 10-2023-0129081 filed on Sep. 26, 2023 in the Korean Intellectual Property Office, the disclosure of which is incorporated by reference herein in its entirety.

### TECHNICAL FIELD

The present inventive concept relates to a substrate processing apparatus and a substrate processing method using the same, and more particularly, to a substrate processing apparatus employing a deposition period and a substrate processing method using the same.

### DISCUSSION OF RELATED ART

A semiconductor device can be produced using a variety of processes, such as photolithography, etching process, deposition, and plating. In the fabrication of semiconductor devices, plasma may be used during the etching process. Radio-frequency (RF) power may be applied to a plasma electrode to generate and control the plasma. The etching process may be performed while the RF power applied to the plasma electrode.

### SUMMARY

An embodiment of the present inventive concept provides a substrate processing apparatus capable of preventing a mask from being damaged and a substrate processing method using the same.

An embodiment of the present inventive concept provides a substrate processing apparatus that increases etch selectivity and a substrate processing method using the same.

An embodiment of the present inventive concept provides a substrate processing apparatus that can easily perform a high aspect ratio contact (HARC) process and a substrate processing method using the same.

According to an embodiment of the present inventive concept, there is provided a substrate processing method including: placing a substrate in a substrate processing apparatus; applying source power to the substrate processing apparatus; and applying bias power to the substrate processing apparatus, wherein applying the source power to the substrate processing apparatus includes: providing the substrate processing apparatus with a first radio-frequency (RF) power with a first pulse having a first period; and providing the substrate processing apparatus with a second RF power with a second pulse having a second period, wherein the first period is longer than the second period.

According to an embodiment of the present inventive concept, there is provided a substrate processing method including: placing a substrate in a substrate processing apparatus; and processing the substrate in the substrate processing apparatus, wherein processing the substrate includes: performing a deposition process on the substrate; and performing an etching process on the substrate, wherein performing the deposition process on the substrate includes providing the substrate processing apparatus with a first RF power with a first pulse having a first period, wherein performing the etching process on the substrate includes: providing the substrate processing apparatus with a second RF power with a second pulse having a second period; and applying a bias power to the substrate processing apparatus, wherein the first RF power is greater than the second RF power.

According to an embodiment of the present inventive concept, there is provided a substrate processing apparatus including: a process chamber that includes a process space; a chuck in the process chamber; a plasma electrode in the process chamber; a bias power generator that applies a bias power to the plasma electrode; a source power generator that applies a source power to the plasma electrode; and a synchronizing pulse signal generator connected to each of the bias power generator and the source power generator, wherein the chuck includes: a chuck body that supports a substrate; and a chuck electrode in the chuck body, wherein the synchronizing pulse signal generator and the source power generator apply a first RF power and a second RF power to the plasma electrode, wherein the first RF power includes a first pulse having a first period, wherein the second RF power includes a second pulse having a second period, wherein the first period is longer than the second period, and wherein the first RF power is greater than the second RF power.

### BRIEF DESCRIPTION OF THE DRAWINGS

FIG. 1 illustrates a cross-sectional view showing a substrate processing apparatus according to an embodiment of the present inventive concept.

FIG. 2 illustrates an enlarged cross-sectional view showing section X of FIG. 1.

FIG. 3 illustrates a flowchart showing a substrate processing method according to an embodiment of the present inventive concept.

FIGS. 4, 5, 6 and 7 illustrate cross-sectional views showing a substrate processing method according to the flowchart of FIG. 3.

FIGS. 8 and 9 illustrate graphs showing power applied to a plasma electrode in a substrate processing method according to the flowchart of FIG. 3.

FIGS. 10, 11, 12, 13 and 14 illustrate graphs showing power applied to a plasma electrode in a substrate processing method according to the flowchart of FIG. 3.

FIG. 15 illustrates a cross-sectional view showing a substrate processing apparatus according to an embodiment of the present inventive concept.

### DETAILED DESCRIPTION OF THE EMBODIMENTS

The following will now describe some embodiments of the present inventive concept with reference to the accompanying drawings. Like reference numerals may indicate like components throughout the description.

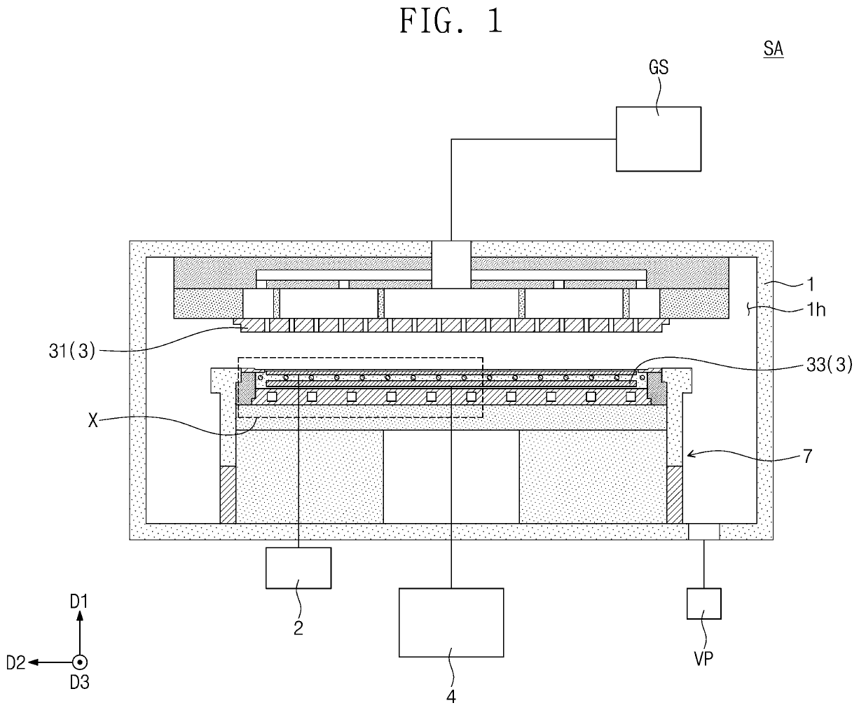

FIG. 1 illustrates a cross-sectional view showing a substrate processing apparatus according to an embodiment of the present inventive concept.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called a vertical direction. Each of the second direction D2 and the third direction D3 may be called a horizontal direction.

Referring to FIG. 1, a substrate processing apparatus SA may be provided. The substrate processing apparatus SA may perform an etching process and/or a deposition process on a substrate. For example, the substrate processing apparatus SA may repeatedly perform an etching process and a deposition process on a substrate. A term “substrate” used in this description may denote a silicon (Si) wafer, but the present inventive concept is not limited thereto. The substrate processing apparatus SA may use plasma to process a substrate. The substrate processing apparatus SA may generate plasma in various ways. For example, the substrate processing apparatus SA may be a capacitively coupled plasma (CCP) apparatus and/or an inductively coupled plasma (ICP) apparatus. For convenience, the following will illustrate and discuss a CCP type substrate processing apparatus. The substrate processing apparatus SA may include a process chamber 1, a chuck 7, a plasma electrode 3, a direct-current (DC) power generator 2, a radio-frequency (RF) power generator 4, a vacuum pump VP, and a gas supply GS.

The process chamber 1 may provide a process space 1h. A substrate process may be performed in the process space 1h. The process space 1h may be isolated from an external space. For example, the walls of the process chamber 1 may isolate the process space 1h from the outside. During a substrate process, the process space 1h may be in a substantial vacuum state. The process chamber 1 may have a cylindrical shape, but the present inventive concept is not limited thereto.

The chuck 7 may be positioned in the process chamber 1. For example, the chuck 7 may be positioned in the process space 1h. The chuck 7 may support and/or hold a substrate. A substrate process may be performed in a state where a substrate is located on the chuck 7. The chuck 7 will be further discussed in detail below.

The plasma electrode 3 may be positioned in the process chamber 1. For example, the plasma electrode 3 may be positioned in the process space 1h. The plasma electrode 3 may include an upper electrode 31 and a lower electrode 33.

The upper electrode 31 may be disposed above and spaced apart from the chuck 7. An empty space may be provided between the upper electrode 31 and the chuck 7. The upper electrode 31 may include a plurality of gas holes. For example, the upper electrode 31 may include a showerhead. The upper electrode 31 may be connected to the gas supply GS. A gas supplied from the gas supply GS may be uniformly sprayed through the upper electrode 31 into the process space 1h.

The lower electrode 33 may be positioned in the chuck 7. The lower electrode 33 may face the upper electrode 31. The lower electrode 33 may be electrically connected to the RF power generator 4. The lower electrode 33 may be provided with RF power and/or bias power from the RF power generator 4. The lower electrode 33 may form an electric field and/or a magnetic field in the process space 1h. The lower electrode 33 may generate plasma in the process space 1h. The lower electrode 33 may control the plasma. The lower electrode 33 may include a conductive material. For example, the lower electrode 33 may include aluminum (Al). The lower electrode 33 may have a disk shape, but the present inventive concept is not limited thereto. The lower electrode 33 will be further discussed in detail below.

The DC power generator 2 may apply DC power to the chuck 7. The DC power applied from the DC power generator 2 may rigidly secure a substrate on a certain position on the chuck 7.

The RF power generator 4 may supply the plasma electrode 3 with RF power. For example, the RF power generator 4 may supply the lower electrode 33 with RF power and/or bias power. This way, it is possible to control plasma in the process space 1h. A detailed description thereof will be further discussed below.

The vacuum pump VP may be connected to the process space 1h. The vacuum pump VP may apply a vacuum pressure to the process space 1h during a substrate process.

The gas supply GS may supply the process space 1h with gas. The gas supply GS may include a gas tank, a compressor, and a valve. Plasma may be generated from a portion of gas supplied from the gas supply GS to the process space 1h.

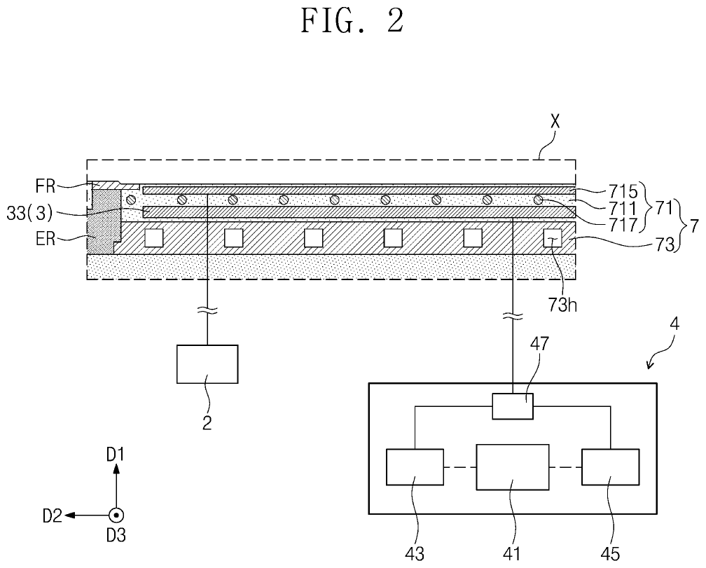

FIG. 2 illustrates an enlarged cross-sectional view showing section X of FIG. 1.

Referring to FIG. 2, the chuck 7 may include an upper chuck 71 and a cooling plate 73.

A substrate may be disposed on the upper chuck 71. The upper chuck 71 is designed to securely hold a substrate in a specific position. The upper chuck 71 may include a chuck body 711, a chuck electrode 715, and a heater 717. The chuck body 711, the heater 717 and the chuck electrode 715 may be arranged in sequence.

The chuck body 711 may have a cylindrical shape. The chuck body 711 may include a ceramic, but the present inventive concept is not limited thereto. A substrate may be disposed on a top surface of the chuck body 711. The chuck body 711 may be surrounded by a focus ring FR and/or an edge ring ER. The lower electrode 33 may be disposed in the chuck body 711.

The chuck electrode 715 may be positioned in the chuck body 711. The chuck electrode 715 may be positioned over the lower electrode 33. For example, the chuck electrode 715 and the lower electrode 33 may face each other. DC power may be applied to the chuck electrode 715. For example, the DC power generator 2 may apply DC power to the chuck electrode 715 via a DC power line. The DC power applied to the chuck electrode 715 can securely hold a substrate in a specific position on the chuck body 711. The chuck electrode 715 may include aluminum (Al), but the present inventive concept is not limited thereto.

The heater 717 may be positioned in the chuck body 711. The heater 717 may be positioned between the chuck electrode 715 and the lower electrode 33. The heater 717 may include a hot wire. For example, the heater 717 may include a concentrically circular shaped hot wire. The heater 717 may radiate heat to its surrounding environment. Therefore, the chuck body 711 may have an increased temperature.

The cooling plate 73 may be positioned below the upper chuck 71. For example, the upper chuck 71 may be positioned on the cooling plate 73. The cooling plate 73 may include a cooling hole 73h. Cooling water may flow in the cooling hole 73h. The cooling water in the cooling hole 73h may absorb heat from the cooling plate 73.

The RF power generator 4 may be electrically connected to the lower electrode 33. The RF power generator 4 may provide the lower electrode 33 with source power and/or bias power via an RF power line. The RF power generator 4 may include a synchronizing pulse signal generator 41, a source power generator 43, a bias power generator 45, and a matcher 47.

The synchronizing pulse signal generator 41 may generate a pulse. The synchronizing pulse signal generator 41 may be electrically connected to each of the source power generator 43 and the bias power generator 45.

The source power generator 43 may generate source power. For example, the source power generator 43 may generate RF power. The RF power generated by the source power generator 43 may be changed into a pulse type by the synchronizing pulse signal generator 41. For example, the RF power may be converted into a pulse type by the synchronizing pulse signal generator 41. The pulse-type source power generated by the source power generator 43 and the synchronizing pulse signal generator 41 may be transmitted through the matcher 47 to the lower electrode 33.

The bias power generator 45 may generate bias power. For example, the bias power generator 45 may generate a sinusoidal wave, a non-sinusoidal wave, and/or RF power. The sinusoidal wave generated by the bias power generator 45 may include a square wave pulse, but the present inventive concept is not limited thereto. The bias power generated by the bias power generator 45 may be changed into a pulse type by the synchronizing pulse signal generator 41. For example, the bias power may be converted into a pulse type by the synchronizing pulse signal generator 41. The pulse-type bias power generated by the bias power generator 45 and the synchronizing pulse signal generator 41 may be transmitted through the matcher 47 to the lower electrode 33. The matcher 47 may include a filter that mixes RF power and a non-sinusoidal wave, but the present inventive concept is not limited thereto. A detailed description thereof will be further discussed below.

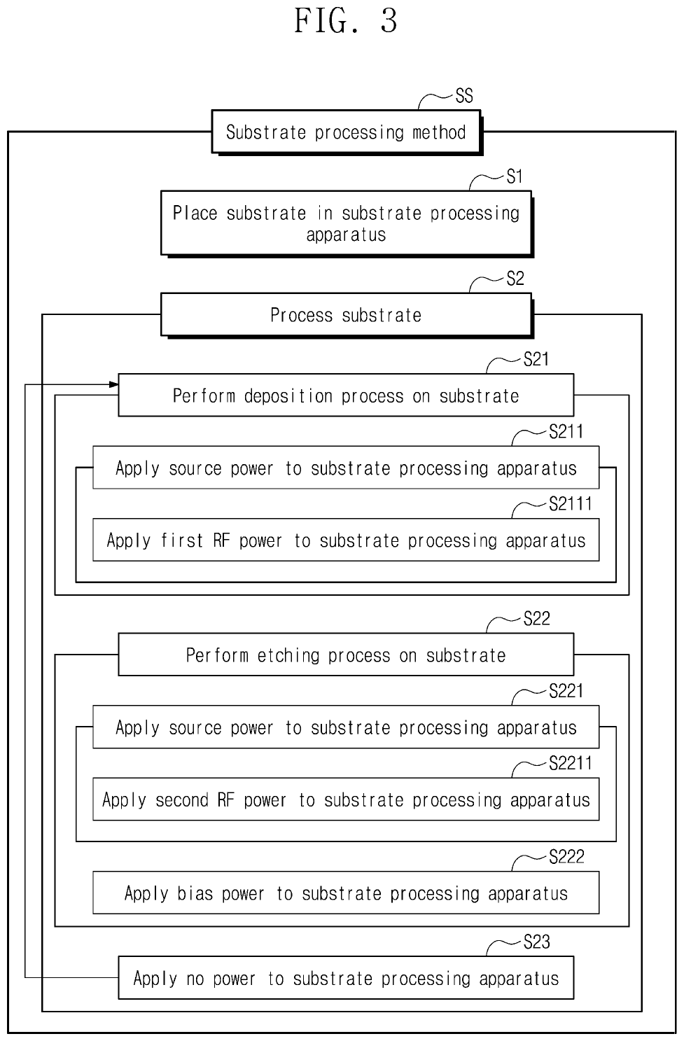

FIG. 3 illustrates a flowchart showing a substrate processing method according to an embodiment of the present inventive concept.

Referring to FIG. 3, a substrate processing method SS may be provided. The substrate processing method SS may be a way of processing a substrate by using the substrate processing apparatus SA discussed with reference to FIGS. 1 and 2. The substrate processing method SS may include placing a substrate into a substrate processing apparatus (S1) and processing the substrate (S2).

The substrate processing step S2 may include performing a deposition process on the substrate (S21), performing an etching process on the substrate (S22), and applying no power to the substrate processing apparatus (S23).

The deposition process step S21 may include applying a source power to the substrate processing apparatus (S211).

The source power apply step S221 may include applying a first RF power to the substrate processing apparatus (S2111).

The etching process step S22 may include applying a source power to the substrate processing apparatus (S221) and applying a bias power to the substrate processing apparatus (S222).

The source power apply step S221 may include applying a second RF power to the substrate processing apparatus (S2211).

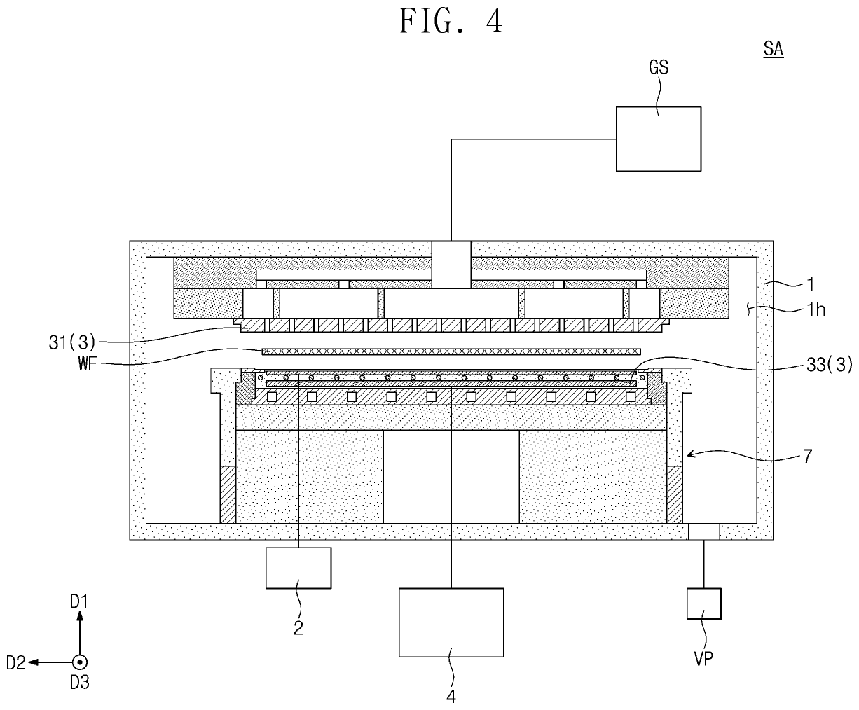

The substrate processing method SS will be discussed in detail below with reference to FIGS. 4 to 9.

FIGS. 4 to 7 illustrate cross-sectional views showing a substrate processing method according to the flowchart of FIG. 3.

Referring to FIGS. 3, 4, and 5, the substrate placement step S1 may include placing a substrate WF on the chuck 7. The substrate WF may include, for example, a silicon (Si) wafer. A robot arm may introduce the substrate WF into the process chamber 1. The substrate WF inserted into the process space 1h may be disposed on a top surface of the chuck 7. The chuck 7 may rigidly secure the substrate WF in a specific position. For example, when the DC power generator 2 applies DC power to the chuck electrode (see 715 of FIG. 2), the chuck electrode 715 may secure the substrate WF in a specific position on the chuck 7. In a state where the substrate WF is loaded on the chuck 7, a process gas may be introduced into the process space 1h. For example, the process gas supplied from the gas supply GS may be distributed through the upper electrode 31 and then introduced into the process space 1h.

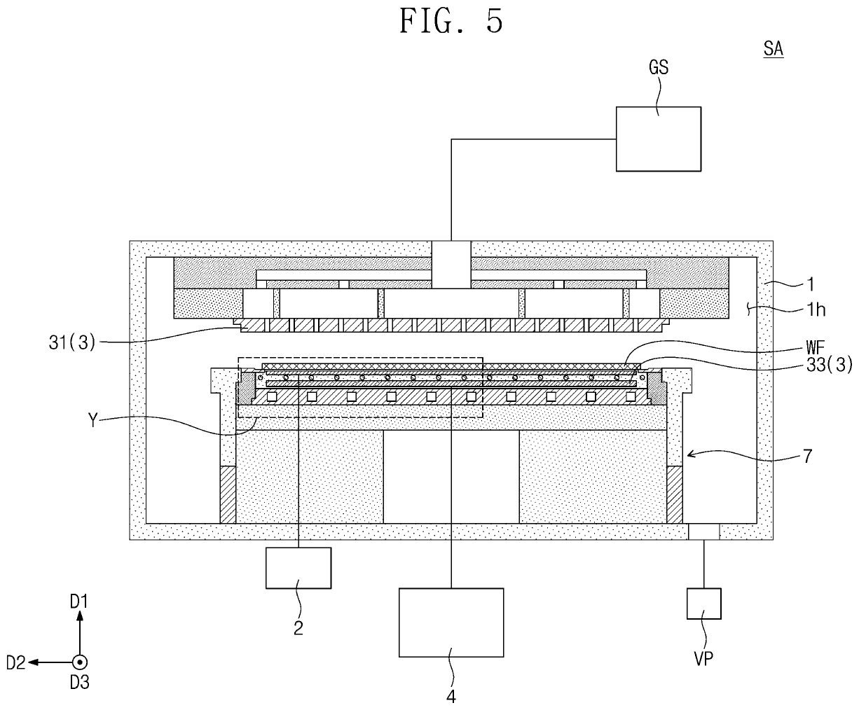

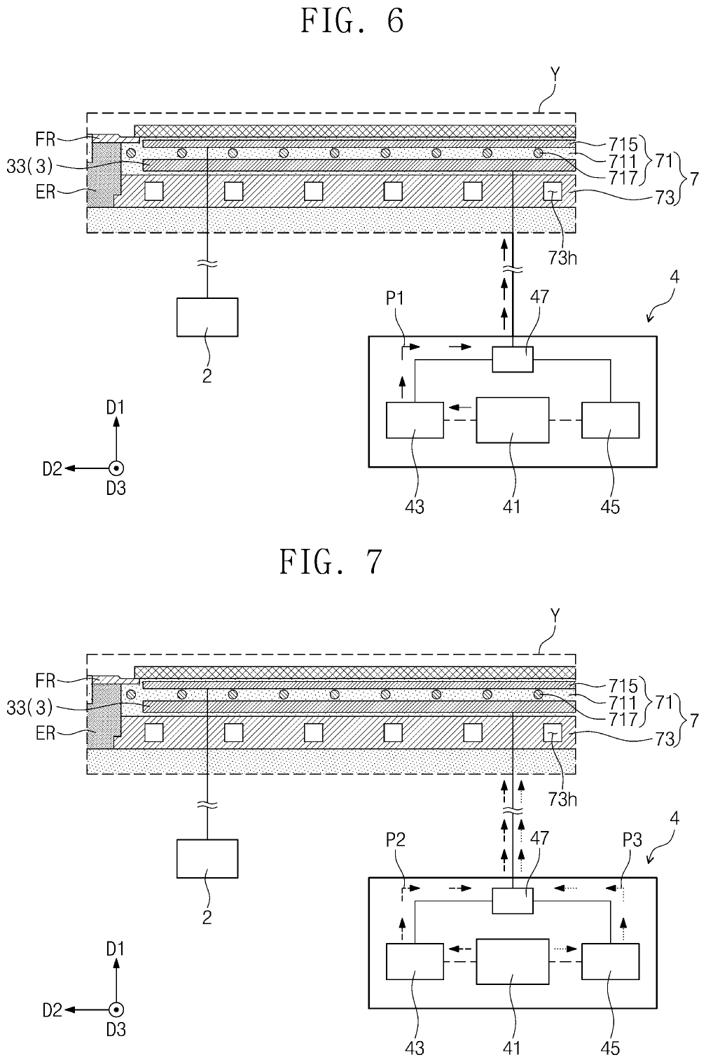

Referring to FIGS. 3 and 6, the first RF power apply step S2111 may include allowing the RF power generator 4 to supply the substrate processing apparatus (see SA of FIG. 5) with a first RF power P1. For example, the synchronizing pulse signal generator 41 and the source power generator 43 may apply the first RF power P1 to the lower electrode 33. The first RF power generated by the synchronizing pulse signal generator 41 and the source power generator 43 may be transmitted through the matcher 47 to the lower electrode 33. The first RF power P1 may be a pulse-type RF. A pulse of the first RF power P1 may be referred to as a first pulse. A period of the first pulse may be referred to as a first period. The first RF power P1 may generate plasma in the process space (see 1h of FIG. 5). The plasma in the process space 1h may be used to perform a deposition process on the substrate (see WF of FIG. 5). For example, in the deposition process, a deposition action may be executed on a mask in the substrate WF. The first RF power P1 will be further discussed in detail below.

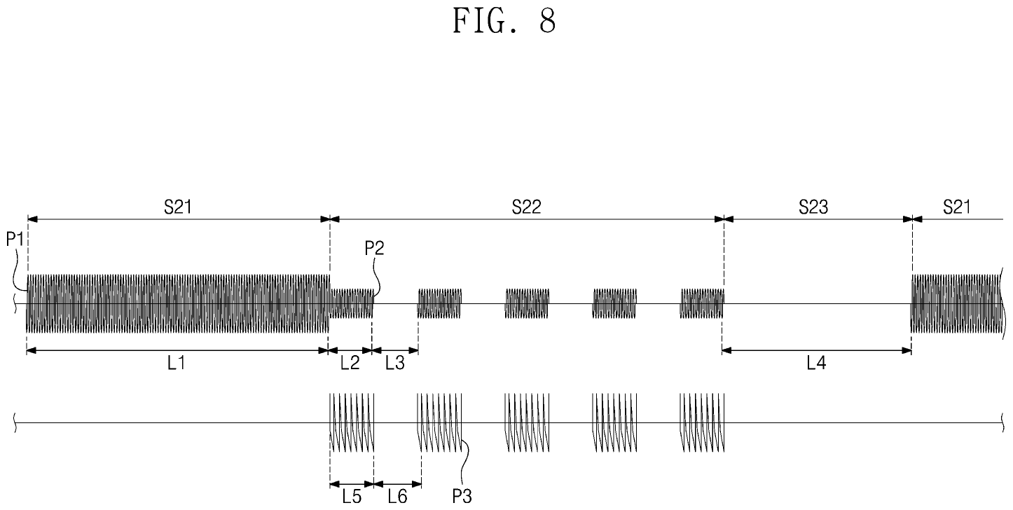

Referring to FIGS. 3 and 7, The second RF power apply step S2211 may be performed after the first RF power (see P1 of FIG. 6) stops being supplied. The second RF power apply step S2211 may include allowing the RF power generator 4 to supply the substrate processing apparatus (see SA of FIG. 5) with a second RF power P2. For example, the synchronizing pulse signal generator 41 and the source power generator 43 may apply the second RF power P2 to the lower electrode 33. The second RF power generated by the synchronizing pulse signal generator 41 and the source power generator 43 may be transmitted through the matcher 47 to the lower electrode 33. The second RF power P2 may be a pulse-type RF. A pulse of the second RF power P2 may be referred to as a second pulse. A period of the second pulse may be referred to as a second period. The second period may be shorter than the first period. As shown in FIG. 8, the second RF power P2 may be less than the first RF power (see P1 of FIG. 6). For example, the first RF power P1 may be greater than the second RF power P2. The present inventive concept, however, is not limited thereto. For example, the first RF power P1 may be less than the second RF power P2. The second RF power P2 may generate plasma in the process space (see 1h of FIG. 5). The second RF power P2 will be further discussed in detail below.

The bias power apply step S222 may be performed after the first RF power (see P1 of FIG. 6) stops being supplied. At least a portion of the bias power apply step S222 may be performed simultaneously with, for example, the second RF power apply step S2211. The bias power apply step S222 and the first RF power apply step S2111 may not overlap each other in terms of time. For example, the bias power apply step S222 may not overlap the first RF power apply step S2111. The present inventive concept, however, is not limited thereto, and the bias power apply step S222 and the first RF power apply step S2111 may overlap each other in terms of time. In the case where the bias power apply step S222 and the first RF power apply step S2111 overlap, in the first RF power apply step S2111, there may be applied a bias power whose output is equal to or less than about 50% of a maximum output of the bias power. The bias power apply step S222 may include allowing the RF power generator 4 to supply the substrate processing apparatus (see SA of FIG. 5) with a bias power P3. For example, the synchronizing pulse signal generator 41 and the bias power generator 45 may apply the bias power P3 to the lower electrode 33. The bias power P3 generated by the synchronizing pulse signal generator 41 and the bias power generator 45 may be transmitted through the matcher 47 to the lower electrode 33. The bias power P3 may be a sinusoidal wave or a pulse-type non-sinusoidal wave. Alternatively, the bias power P3 may be a pulse-type RF. A pulse of the bias power P3 may be referred to as a third pulse. A period of the third pulse may be referred to as a third period. The third period may be shorter than the first period. The third period may be, for example, substantially the same as or similar to the second period. The bias power P3 may cause the plasma in the process space 1h to move toward the substrate (see WF of FIG. 5). For example, the bias power P3 may cause the substrate WF to undergo an etching process. The bias power P3 will be further discussed in detail below.

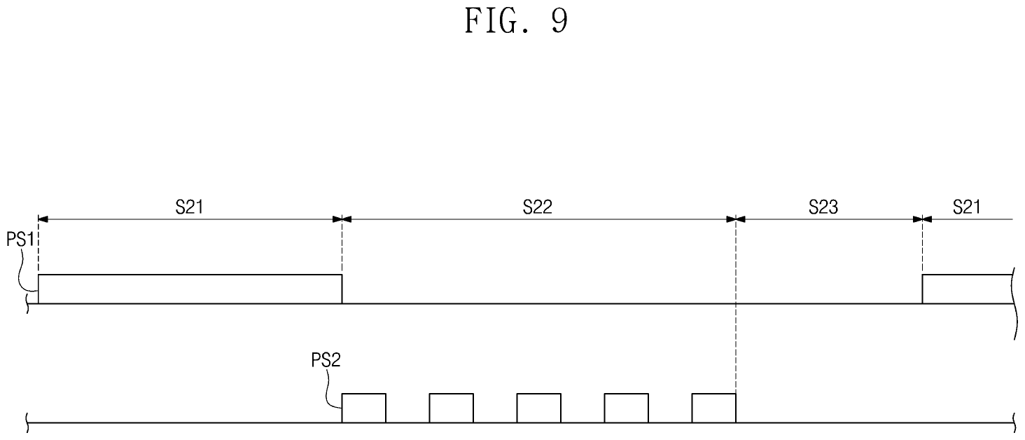

FIGS. 8 and 9 illustrate graphs showing power applied to a plasma electrode in a substrate processing method according to the flowchart of FIG. 3.

Referring to FIGS. 3, 8, and 9, the first RF power apply step S2111 may continue for a first time duration. A first period L1 may include a period of a first pulse PS1 of the first RF power P1. The first time duration may be, for example, substantially the same as or similar to the first period L1. The first time duration may be greater than about 100 milliseconds (ms). The first period L1 may be greater than about 100 ms.

The second RF power apply step S2211 may continue for a second time duration. The second time duration may be greater than, for example, about 100 ms. In a second pulse PS2 of the second RF power P2, the second RF power P2 may be supplied for a first unit time duration L2. In the second pulse PS2 of the second RF power P2, the supply of the second RF power P2 may be interrupted for a second unit time duration L3. In other words, the second RF power P2 may not be supplied during the second unit time duration L3. As discussed above, a second period L2+L3 may include a period of the second pulse PS2 of the second RF power P2. The second period L2+L3 may be shorter than the second time duration. For example, the second period L2+L3 may be less than about 100 ms.

The bias power apply step S222 may continue for a fourth time duration. The fourth time duration may be greater than, for example, about 100 ms. In a third pulse of the bias power P3, the bias power P3 may be supplied for a third unit time period L5. In the third pulse of the bias power P3, the supply of the bias power P3 may be interrupted for a fourth unit time period L6. In other words, the bias power P3 may not be supplied during the fourth unit time period L6. As discussed above, a third period L5+L6 may include a period of the third pulse of the bias power P3. The third period L5+L6 may be shorter than the second time duration. For example, the third period L5+L6 may be less than about 100 ms.

The first RF power apply step S2111 and the second RF power apply step S2211 may be alternately and repeatedly performed.

The no power apply step S23 may be performed after the termination of the second RF power apply step S2211 and before the first RF power apply step S2111 begins again. The no power apply step S23 may continue for a third time duration L4. The third time duration L4 may be greater than about 100 ms. During the no power apply step S23, particles on a substrate may be exhausted. In the no power apply step S23, the first and second RF power P1 and P2 as well as the bias power P3 are not supplied.

According to a substrate processing apparatus and a substrate processing method using the same in accordance with an embodiment of the present inventive concept, a deposition process may be performed on a substrate before an etching process is performed on the substrate. Therefore, a mask of the substrate may not be damaged. As a result, it is possible to increase an etch selectivity with respect to the substrate. In addition, it is possible to easily perform a high aspect ratio contact (HARC) process.

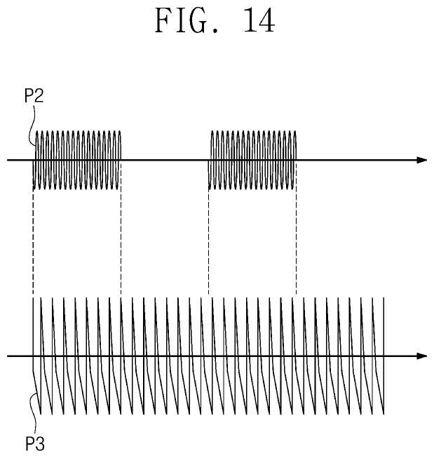

FIGS. 10 and 14 illustrate graphs showing power applied to a plasma electrode in a substrate processing method according to the flowchart of FIG. 3.

The following will omit a description of content substantially the same as or similar to that discussed with reference to FIGS. 1 to 9.

Referring to FIG. 10, when the supply of the second RF power P2 is interrupted, the supply of the bias power P3 may begin. In addition, when the supply of the bias power P3 is interrupted, the supply of the second RF power P2 may begin again. For example, the supply of the second RF power P2 and the bias power P3 may not overlap.

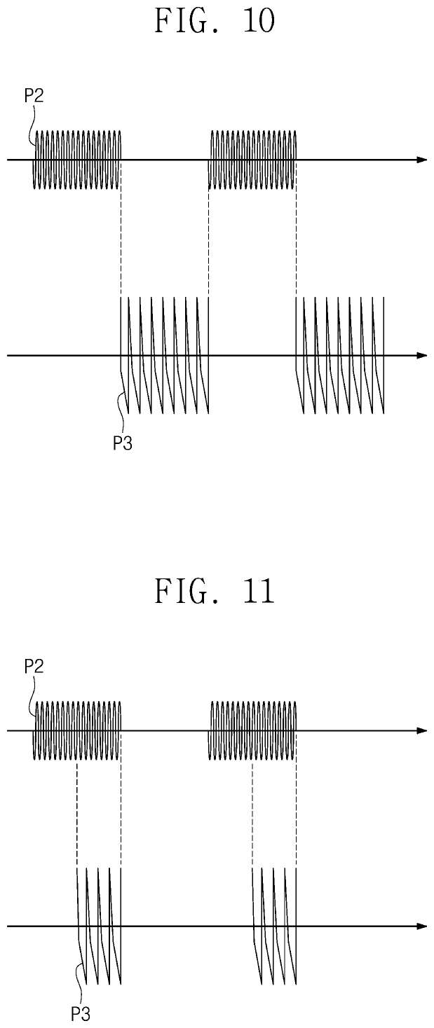

Referring to FIG. 11, when the supply of the second RF power P2 is performed, the supply of the bias power P3 may begin. For example, the supply of the second RF power P2 and the supply of the bias power P3 may overlap. In addition, when the supply of the second RF power P2 is interrupted, the supply of the bias power P3 may be interrupted.

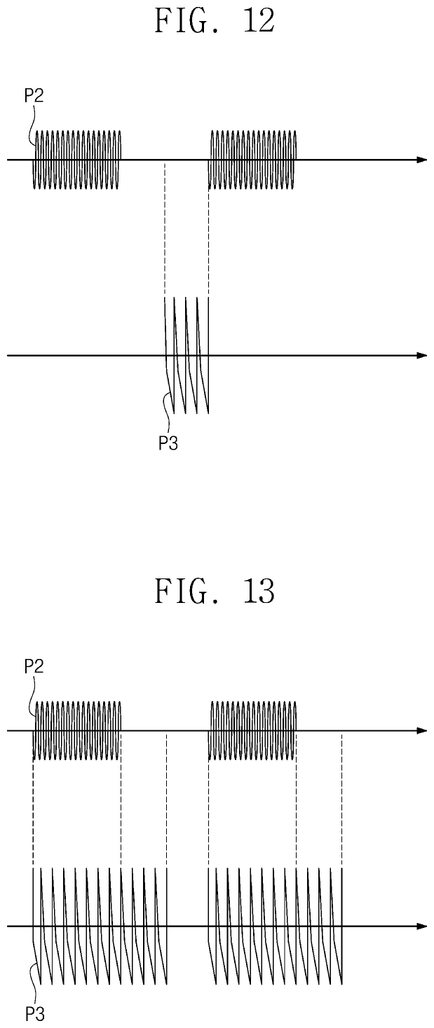

Referring to FIG. 12, when the supply of the second RF power P2 is interrupted, the supply of the bias power P3 may begin. In addition, when the supply of the bias power P3 is interrupted, the supply of the second RF power P2 may begin again.

Referring to FIG. 13, when the supply of the second RF power P2 begins, the supply of the bias power P3 may begin. When the supply of the second RF power P2 is interrupted, the supply of the bias power P3 may be continuously performed. In other words, the bias power P3 may continue to be supplied while the second RF power P2 is interrupted. When the supply of the second RF power P2 is interrupted, the supply of the bias power P3 may also be interrupted.

Referring to FIG. 14, the bias power P3 may have no pulse type. For example, the bias power P3 may be supplied without being interrupted.

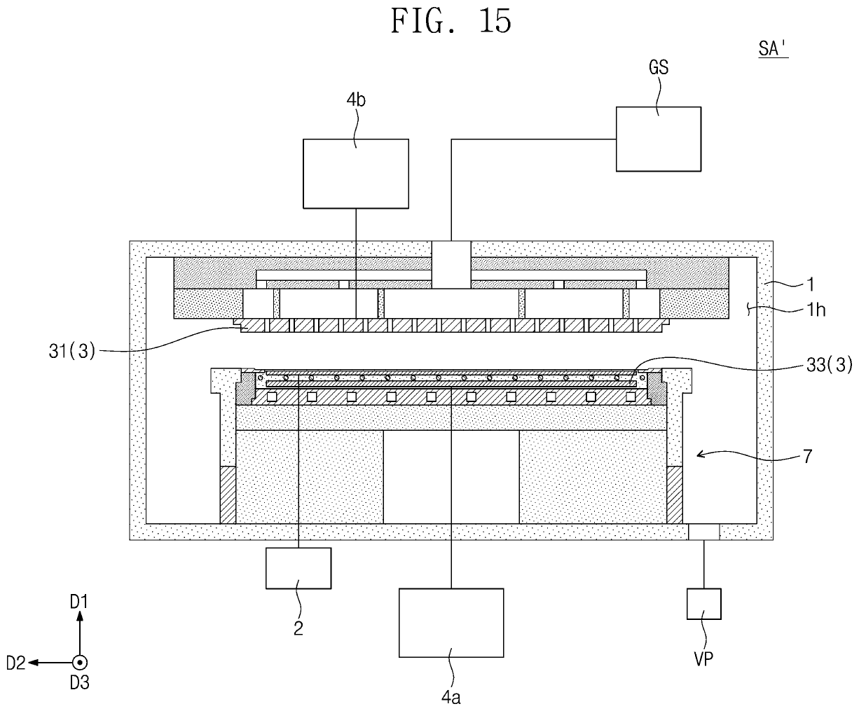

FIG. 15 illustrates a cross-sectional view showing a substrate processing apparatus according to an embodiment of the present inventive concept.

The following will omit a description of components substantially the same as or similar to those discussed with reference to FIGS. 1 to 14.

Referring to FIG. 15, a substrate processing apparatus SA′ may be provided. The substrate processing apparatus SA′ may include a first RF power generator 4a and a second RF power generator 4b. The first RF power generator 4a may be electrically connected to the lower electrode 33 via a power line. The first RF power generator 4a may apply a bias power to the lower electrode 33. The second RF power generator 4b may be electrically connected to the upper electrode 31 via a power line. The second RF power generator 4b may apply a source power to the upper electrode 31. For example, the source power may be supplied not to lower electrode 33 but to the upper electrode 31.

According to a substrate processing apparatus and a substrate processing method using the same of the present inventive concept, a mask may be prevented from being damaged.

According to a substrate processing apparatus and a substrate processing method using the same of the present inventive concept, etch selectively may increase.

According to a substrate processing apparatus and a substrate processing method using the same of the present inventive concept, a high aspect ratio contact (HARC) process may be easily performed.

Effects of the present inventive concept are not limited to the mentioned above, other effects which have not been mentioned above will be clearly understood to those skilled in the art based on the following description.

Although the present inventive concept has been described in connection with embodiments thereof, it will be understood by those skilled in the art that various changes and modifications may be made thereto without departing from the technical spirit and features of the present inventive concept as set forth in the claims. It therefore will be understood that the embodiments described above are illustrative and not limiting.

1. A substrate processing method, comprising:
placing a substrate in a substrate processing apparatus;
applying source power to the substrate processing apparatus; and
applying bias power to the substrate processing apparatus,
wherein applying the source power to the substrate processing apparatus includes:
providing the substrate processing apparatus with a first radio-frequency (RF) power with a first pulse having a first period; and
providing the substrate processing apparatus with a second RF power with a second pulse having a second period,
wherein the first period is longer than the second period.

2. The method of claim 1, wherein the first RF power is greater than the second RF power.

3. The method of claim 1, wherein the first RF power is less than the second RF power.

4. The method of claim 1, wherein applying the bias power to the substrate processing apparatus includes providing the substrate processing apparatus with the bias power with a third pulse having a third period,
wherein the third period is the same as the second period.

5. The method of claim 4, wherein a portion of applying the bias power is performed simultaneously with applying the second RF power.

6. The method of claim 1, wherein the bias power is a non-sinusoidal wave or a sinusoidal wave.

7. The method of claim 1, wherein applying the bias power and the applying the first RF power overlap or do not overlap each other in terms of time.

8. The method of claim 1, wherein
applying the first RF power continues for a first time duration,
applying the second RF power continues for a second time duration,
the first time duration is the same as the first period, and
the second time duration is longer than the second period.

9. The method of claim 8, wherein
each of the first time duration and the second time duration is greater than about 100 milliseconds, and
the second period is equal to or less than about 100 milliseconds.

10. The method of claim 1, wherein applying the first RF power and applying the second RF power are alternately and repeatedly performed.

11. The method of claim 10, further comprising applying no source power to the substrate processing apparatus.

12. The method of claim 11, wherein applying no source power to the substrate processing apparatus is performed after applying the second RF power stops and before applying the first RF power begins again.

13. A substrate processing method, comprising:
placing a substrate in a substrate processing apparatus; and
processing the substrate in the substrate processing apparatus,
wherein processing the substrate includes:
performing a deposition process on the substrate; and
performing an etching process on the substrate,
wherein performing the deposition process on the substrate includes providing the substrate processing apparatus with a first radio-frequency (RF) power with a first pulse having a first period,
wherein performing the etching process on the substrate includes:
providing the substrate processing apparatus with a second RF power with a second pulse having a second period; and
applying a bias power to the substrate processing apparatus,
wherein the first RF power is greater than the second RF power.

14. The method of claim 13, wherein performing the deposition process on the substrate and performing the etching process on the substrate are alternately and repeatedly performed.

15. The method of claim 14, after performing the etching process on the substrate stops and before performing the deposition process on the substrate begins again, further comprising applying no power to the substrate processing apparatus.

16. The method of claim 13, wherein the second period is shorter than the first period.

17. The method of claim 13, wherein the substrate processing apparatus includes:
a process chamber that includes a process space;
a chuck in the process chamber;
an upper electrode overlapping and spaced apart from the chuck; and
a lower electrode in the chuck,
wherein the chuck includes:
a chuck body that supports the substrate; and
a chuck electrode in the chuck body.

18. The method of claim 17, wherein
each of the first RF power and the second RF power is applied to the upper electrode, and
the bias power is applied to the lower electrode.

19. The method of claim 17, wherein each of the first RF power, the second RF power, and the bias power is applied to the lower electrode.

20. The method of claim 13, wherein
performing the deposition process on the substrate continues for a first time duration,
performing the etching process on the substrate continues for a second time duration, and
the first period is the same as the first time duration.

21-23. (canceled)
